(19) United States
(12) Patent Application Publication
(10) Pub. No.: US 2004/0212459 A1
(43) Pub. Date: Oct. 28, 2004

(54) Method for producing a layer with a predefined layer thickness profile

(76) Inventors: Robert Aigner, Unterhaching (DE); Luder Elbrecht, Munich (DE); Stephan Marksteiner, Putzbrunn (DE); Winfried Nessler, Munich (DE); Hans-Jorg Timme, Ottobrunn (DE)

Correspondence Address: BEVER HOFFMAN & HARMS, LLP, TRI-VALLEY OFFICE, 1432 CONCANNON BLVD., BLDG. G, LIVERMORE, CA, 94550, US

(21) Appl. No.: 10/478,751

(22) PCT Filed: May 22, 2001
(86) PCT No.: PCT/EP01/05889

(51) Int. Cl. H03H 9/00

(52) U.S. Cl. 333/197; 333/188; 310/312

(57) ABSTRACT

A method for producing a layer with a locally adapted or predefined layer thickness profile that can be used for to selectively set the natural frequencies of piezoelectric resonant circuits and/or the impedance of other circuit elements. A layer is applied to a substrate, then measured to determine a difference between the initial layer thickness and the predefined layer thickness profile. An ion beam is then used to etch (mill) the layer until it achieves the predefined layer thickness profile.

### FIELD OF THE INVENTION

The invention relates to a method for producing a layer with a predefined or adapted layer thickness profile. The invention relates, in particular, to a method for producing a layer with a predefined or adapted layer thickness profile for carrying out a frequency adjustment in piezoelectric resonant circuits.

### BACKGROUND OF THE INVENTION

The natural frequency of resonant circuits based on piezoelectric thin films in the frequency range above 500 MHz is indirectly proportional to the layer thickness of the piezolayer. The acoustically insulating substructure and also the bottom and the top electrodes constitute an additional mass loading for the resonant circuit which brings about a reduction of the natural frequency. The thickness fluctuations in all these layers determine the range of manufacturing tolerances within which the natural frequency of a specimen of the resonant circuit lies. For sputtering processes in microelectronics, layer thickness fluctuations of 5% are typical, and 1% (1σ) can be achieved with some outlay. These fluctuations occur both statistically from wafer to wafer and systematically between wafer center and edge.

The thickness tolerances of the individual layers in the acoustic path of resonant circuits based on piezoelectric thin films are essentially stochastically independent of one another. The frequency errors or variations caused by said thickness tolerances therefore accumulate according to the error propagation law. In this case, an overall frequency variation of approximately 2% (1σ) typically results for resonant circuits based on piezoelectric thin films. For applications in the GHz range, however, the natural frequencies of individual resonant circuits must have at least an absolute accuracy of 0.5%. In high-precision applications, a tolerance window of just 0.25% emerges from the specifications.

For highly selective applications, it is necessary to interconnect a plurality of resonant circuits in ladder, lattice or parallel configurations. The individual resonant circuits have to be detuned in a targeted manner with respect to one another in order to achieve the desired characteristic. Preferably, for cost reasons, all the resonant circuits of a device are produced from a piezolayer of constant thickness. The frequency tuning is generally effected by means of additive layers in the acoustically active stack. For each natural frequency that occurs, it is necessary to produce an additional layer of different thickness. This generally requires in each case a deposition or etching step, connected with a lithography step. In order to limit this outlay, only topologies with which only two natural frequencies are set are usually produced.

The document U.S. Pat. No. 5,587,620 describes methods in which a frequency adjustment is achieved by means of a device-specific deposition of an additional layer. However, such methods, which cannot be carried out at the wafer level, are associated with comparatively high manufacturing costs. Furthermore, the document U.S. Pat. No. 5,587,620 proposes a frequency adjustment by way of a temperature variations. In the document EP 0 771 070 A2, a frequency adjustment is achieved by further passive components being supplementarily connected. Unfortunately, such methods generally have an excessively small frequency effect or lead to other undesirable alterations of the characteristic of the resonant circuit.

### SUMMARY OF THE INVENTION

Therefore, the present invention is based on the object of providing a method for producing a layer with a locally adapted or predefined layer thickness profile which reduces or entirely avoids the difficulties mentioned. In particular, the present invention is based on the object of providing a method which can be used for setting the natural frequencies of piezoelectric resonant circuits.

The invention provides a method for producing a layer with a locally adapted or predefined layer thickness profile which comprises the following steps:

a) at least one layer is applied to a substrate,

b) a removal profile is determined for the applied layer, and

c) at least one ion beam is guided over the layer at least once, so that, at the location of the ion beam, the layer is etched locally in accordance with the removal profile and a layer with a locally adapted or predefined layer thickness profile is produced.

The method according to the invention has the advantage that both random fluctuations from wafer to wafer and systematic fluctuations between wafer center and wafer edge can be corrected. The method according to the invention permits a cost-efficient correction of these fluctuations with comparatively simple equipment. Furthermore, the method according to the invention can be used to produce layers with regions whose thicknesses differ in a targeted manner. The method according to the invention additionally has the advantage that it can be used universally for any desired layer materials and layer thicknesses. Furthermore, the method according to the invention can be applied a number of times if the removal profile could not be achieved at the first attempt. In this case, the machine throughput profits considerably from advances which emerge in the methods for layer deposition.

Preferably, the layer is processed over the entire wafer, the method according to the invention being adapted to the requirements which are predefined by industrial mass production, for example with regard to the throughput. The processing time of the method according to the invention lie in the range of between 1 and 60 minutes.

In accordance with one preferred embodiment of the invention, the method according to the invention is used for setting the natural frequencies of piezoelectric resonant circuits. A method which allows direct influencing of the natural frequency is obtained in this way. In this case, the method can be applied before, during and after completion of the oscillator stack. It is preferred, however, if the method is carried out on a resonant circuit that has already essentially been completed. Furthermore, the method according to the invention has the advantage that it is possible to carry out a frequency adjustment at the wafer level and that it is possible to set the natural frequencies of piezoelectric resonant circuits over a large trimming range of up to 20%.

In accordance with one preferred embodiment of the invention, the extent of the ion beam is greater than 1 mm, preferably greater than 5 mm. Furthermore, it is preferred if the extent of the ion beam is less than 100 mm, preferably less than 50 mm.

In accordance with one preferred embodiment of the invention, an argon ion beam is used as the ion beam. Furthermore, it is preferred if an ion beam with a Gaussian current density distribution is used. In this case, the half-value width of the ion beam is understood to be the extent of the ion beam. In this case, it is particularly preferred if the ion beam is guided over the layer in tracks and the track spacing is less than the half-value width of the ion beam.

Furthermore, it is particularly preferred if an ion beam with a homogeneous current density distribution is used. In this case, it is particularly preferred if the ion beam is guided over the layer in tracks and the track spacing is less than the extent of the ion beam. In both cases, the control data for the ion beam, for example for the displacement table and the source control, can be obtained from an inverse convolution of the desired removal profile with the so-called “etching footprint” of the ion beam. Furthermore, it is particularly preferred if the local etching of the layer is controlled by the current density of the ion beam and/or the speed with which the ion beam is guided over the layer.

In accordance with a further preferred embodiment, before step c), a mask, in particular a resist mask, is applied to the layer, which leaves open only the regions of the layer which are to be etched.

If the method according to the invention is used for setting natural frequencies in piezoelectric resonant circuits, then it is particularly preferred if an electrical measurement of the natural frequency of the piezoelectric resonant circuits is carried out in order to determine the removal profile for the applied layer.

### BRIEF DESCRIPTION OF THE DRAWINGS

The invention is illustrated in greater detail below with reference to figures of the drawing, in which:

FIG. 1 shows a piezoelectric resonant circuit produced with the aid of the method according to the invention,

FIGS. 2, 3 and 4 show an embodiment of the method according to the invention using the example of the piezoelectric resonant circuit shown FIG. 1,

FIG. 5 shows a typical removal profile of a predominantly rotationally symmetrical center-edge error in the thickness of a metal layer,

FIG. 6 shows a measured removal profile of an ion beam etching, and

FIGS. 7 and 8 show a further embodiment of the method according to the invention.

### DETAILED DESCRIPTION OF THE DRAWINGS

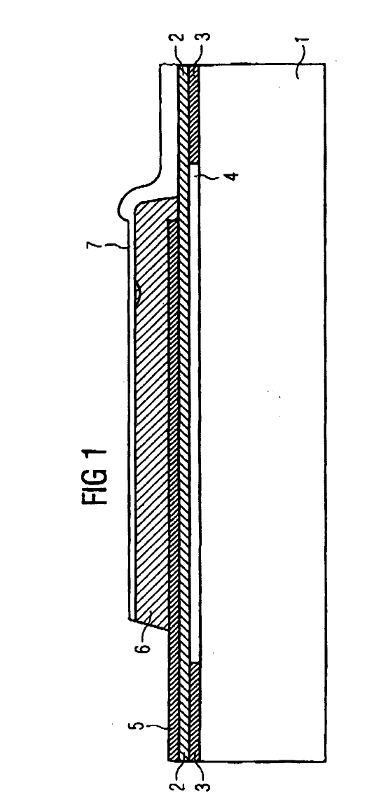

FIG. 1 shows a piezoelectric resonant circuit produced with the aid of the method according to the invention. Situated on a wafer 1 is a carrier layer 2, which is preferably silicon and below which a cavity 4 in an auxiliary layer 3, e.g. made of oxide, is situated in the region of a layer structure provided as resonant circuit. The cavity typically has the width dimension of about 200 μm. Situated on the carrier layer 2 is the layer structure of the resonant circuit comprising a lower electrode layer 5 provided for the bottom electrode, a piezolayer 6 and an upper electrode layer 7 provided for the top electrode. The electrode layers 5, 7 are preferably metal, and the piezolayer 6 is e.g. AlN, ZnO or PZT ceramic (PbZrTi). This layer structure overall typically has the thickness of about 5 μm. Instead of the cavity, it is also possible to use other acoustically insulating substructures, such as acoustic mirrors, for example.

In order to set one of the desired natural frequency, the upper electrode layer 7 was produced with a locally adapted thickness profile. In the present example, this means that the upper electrode layer 7 made significantly thinner in the region of the piezoelectric resonant circuit directly above the piezolayer 6 than in the remaining regions. In this case, the thickness profile of the upper electrode layer 7 as shown in FIG. 1 was produced in accordance with a method according to the invention.

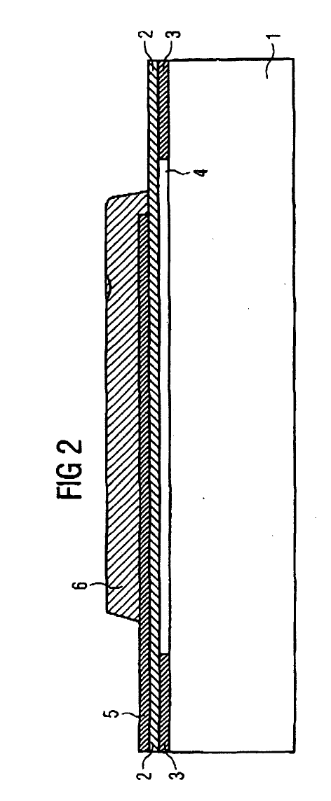

FIGS. 2 to 4 show an embodiment of the method according to the invention using the example of the piezoelectric resonator shown in FIG. 1. The starting point in this case is the structure shown in FIG. 2, which structure corresponds to a piezoelectric resonant circuit without an upper electrode layer 7. The structure shown in FIG. 2 thus acts as a kind of substrate for the subsequent deposition of the upper electrode layer 7.

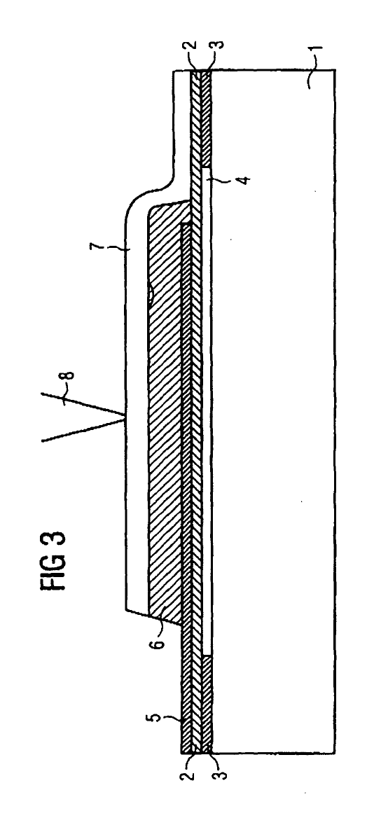

A relatively thick metal layer, for example a tungsten layer, is subsequently produced by means of a sputtering method. Instead of a sputtering method, it is also possible to use a CVD method or an electrochemical method. After the application of the metal layer, the removal profile for the metal is determined. In the present example, this determination is effected at the location of the resonant circuit by measuring the natural frequency of the resonant circuit. For this purpose, a needle contact 8 is guided onto the metal layer and the impedance of the resonant circuit is measured as a function of the frequency of the electrical excitation (FIG. 3). The natural frequency can be determined from the impedance curve thus obtained. The measured natural frequency is then compared with the desired natural frequency for the piezoelectric resonant circuit, as a result of which that part of the layer which must be removed can be calculated. Since these are parts of the layer which have different thicknesses in the case of different resonant circuits on the wafer 1 on account of the thickness fluctuations of the layer and/or on account of different functions of the resonant circuits, a specific removal profile results over the entire wafer and is subsequently used to control the ion beam etching.

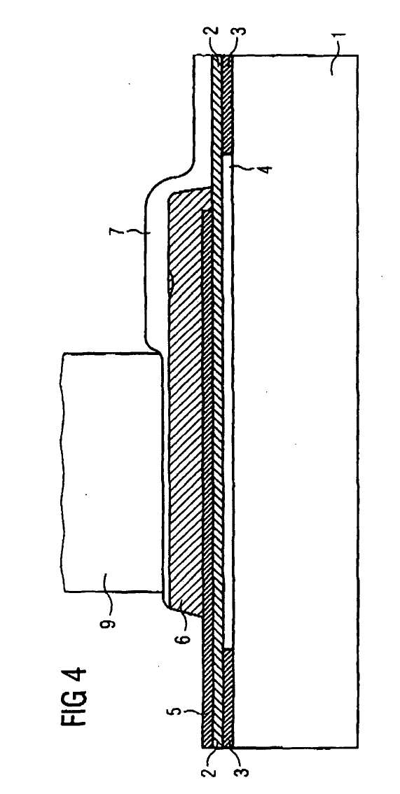

An ion beam 9 is subsequently guided over the layer at least once, so that, at the location of the ion beam, the metal layer is etched (ion milled) locally in accordance with the removal profile and a metal layer 7 with a layer thickness profile that is locally adapted to the desired natural frequency of the resonant circuit is produced (FIG. 4). By mechanically scanning the wafer with a Gaussian ion beam (which has a corresponding diameter), it is possible to realize a locally controllable removal. If the wafer is scanned in tracks, then either the beam current or the scanning speed may be controlled in accordance with the locally required removal. The scanning is effected in any desired sequence from tracks in the x and y direction (as an alternative, concentric rings or spirals are also possible) whose track spacing is significantly less than half-value width of the ion beam.

The beam diameter is chosen in accordance with the largest removal gradient required; small beam diameters permit steeper gradients but produce globally lower volume removal per unit time. The control data for the displacement table and the source control are obtained from an inverse convolution of the desired removal profile with the so-called “etching footprint” of the ion beam.

Instead of an ion beam with a Gaussian current density distribution, it is also possible, of course, to use an ion beam with a homogeneous current density distribution. In this case, the track spacing should be less than the extent (diameter) of the ion beam.

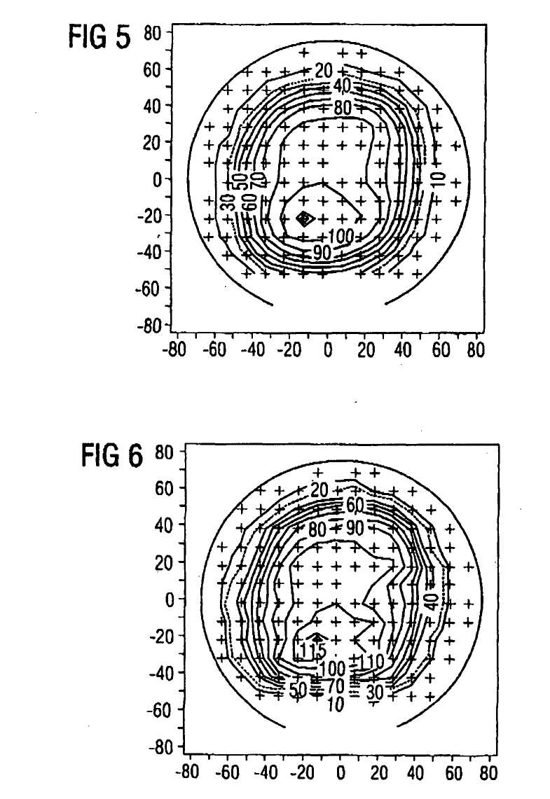

FIG. 5 shows a typical removal profile of a predominantly rotationally symmetrical center-edge error in the thickness of a metal layer, as can be calculated from an electrical frequency measurement at approximately 150 wafer positions, corresponding to 150 piezoelectric resonant circuits. FIG. 6 shows the corresponding measured removal profile of an ion beam etching using a Gaussian Ar ion beam (half-value diameter of between 5 and 50 mm) which was achieved with speed control in the x direction. The track spacing in the y direction was about 10% of the half-value diameter. The residual error was in the region of between 1 and 20 nm. The method according to the invention has the advantage that it is possible to carry out a frequency adjustment at the wafer level, and that it is possible to set the natural frequencies of piezoelectric resonant circuits over a large trimming range of up to 20% and with a frequency accuracy of 0.25%.

A layer with a layer thickness profile that is locally adapted to the desired natural frequency of the resonant circuits was produced in the case of the previously described embodiment of the method according to the invention. However, the adaptation of the layer thickness profile need not necessarily be effected with regard to the natural frequency of a resonant circuit. With the method according to the invention, it is also possible, for example, to produce a multiplicity of resistors and/or capacitors with different impedance values but identical lateral dimensions. The method according to the invention is then utilized for producing a layer thickness profile that is locally adapted to the respective resistor and/or capacitor. Furthermore, the method according to the invention can be used to produce a multiplicity of diaphragms with different mechanical parameters but identical lateral dimensions. The method according to the invention is then utilized for producing a layer thickness profile of the diaphragm material which is adapted to the respective diaphragm.

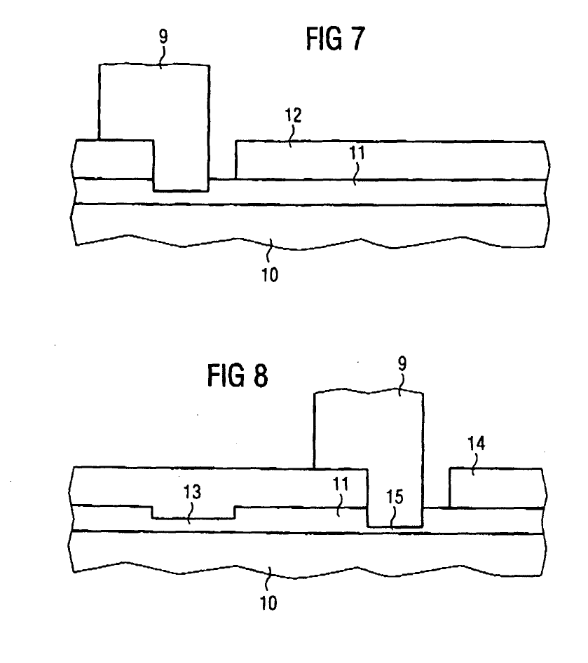

FIGS. 7-8 show a further embodiment of the method according to the invention. A relatively thick layer 11 is produced on a substrate 10. Instead of a sputter method, it is also possible to use a CVD method or an electrochemical method. Depending on the desired application, the substrate 10 may be an insulating layer, for example an oxide layer, and the layer 11 may be a conductive layer, for example a metal layer. Such a choice of materials would be suitable for example for producing resistors with predefined, different resistance values. By contrast, if the intention is to produce capacitors with predefined, different impedance values, then a conductive layer, for example a metal layer, would be chosen as the substrate 10 and an insulating layer, for example an oxide layer, would be chosen as the layer 11.

After the application of the layer 11 and a possible patterning of the layer 11, the removal profile for the layer 11 is determined. For the case where the intention is to produce resistors with predefined, different resistance values, the removal profile may be determined for example by means of a resistance measurement. However, it is also possible to use interferometric measurements.

The present example assumes that resistors with two different resistance values are intended to be produced in a manner distributed over the wafer. Therefore, a resist layer is subsequently applied and developed to produce a resist mask 12, which is open at the locations at which the resistors 13 with a first resistance value are intended to be produced. An ion beam etching is subsequently effected, which, at the open locations of the resist mask 12, carries out an etching in accordance with the predefined removal profile with an ion beam 9. All the remaining regions of the layer 11 are protected by the resist mask 12 in this case (FIG. 7).

Once the first ion beam etching has been concluded, the resist mask 12 is removed and a further resist layer is applied and developed to produce a further resist mask 14, which is open at the location at which the resistors 15 with a second resistance value are intended to be produced. An ion beam etching is once again subsequently effected, which, at the open locations of the resist mask 14, carries out an etching in accordance with the predefined removal profile. All the remaining regions of the layer 11 are protected by the resist mask 14 in this case (FIG. 8). Consequently, after the removal of the resist mask 14, a layer 11 with a layer thickness profile that is locally adapted to the respective resistor is obtained.

1. A method for producing a layer with a locally adapted or predefined layer thickness profile, the method comprising:
a) applying at least one layer to a substrate,
b) determining a removal profile for the applied layer based on predetermined correction data, and
c) guiding at least one ion beam over the applied layer at least once, so that, at a location of the applied layer that is struck by the ion beam, the applied layer is etched locally in accordance with the removal profile, thereby producing an etched layer having a layer thickness profile that is in accordance with the predetermined correction data.

2. The method as claimed in claim 1, wherein guiding the ion beam comprises generating said ion beam such that the ion beam has a diameter that is greater than 1 mm.

3. The method according to claim 1, wherein guiding the ion beam comprises generating said ion beam such that the ion beam has a diameter that is greater than 5 mm.

4. The method as claimed in claim 1, wherein guiding the ion beam comprises generating said ion beam such that the ion beam has a diameter an amount that is less than 100 mm.

5. The method according to claim 1, wherein guiding the ion beam comprises generating said ion beam such that the ion beam has a diameter an amount that is less than 50 mm.

6. The method as claimed in claim 1, wherein guiding the ion beam comprises generating an argon ion beam.

7. The method as claimed in claim 1, wherein guiding the ion beam comprises generating the ion beam such that the ion beam has a Gaussian current density distribution.

8. The method as claimed in claim 7, wherein guiding the ion beam comprises scanning the ion beam over the applied layer in tracks, wherein a spacing between adjacent tracks is less than a half-value width of the ion beam.

9. The method as claimed in claim 1, wherein guiding the ion beam comprises generating the ion beam such that the ion beam has a homogeneous current density distribution.

10. The method as claimed in claim 9, wherein guiding the ion beam comprises scanning the ion beam over the applied layer in tracks, wherein a spacing between adjacent tracks is less than a width of the ion beam.

11. The method as claimed in claim 1, wherein guiding the ion beam comprises controlling the local etching of the applied layer by controlling at least one of a current density of the ion beam and a speed at which the ion beam is guided over the applied layer.

12. The method as claimed in claim 1, further comprising, before step c), applying a mask to the applied layer, wherein the mask defines openings only over regions of the applied layer which are to be etched.

13. The method as claimed in claim 1, wherein the applied layer comprises an electrode of a piezoelectric resonant circuit, and wherein guiding the ion beam comprises changing a natural frequency of the piezoelectric resonant circuit from a first frequency to a second frequency.

14. The method as claimed in claim 13, wherein determining the removal profile comprises performing an electrical measurement to determine the natural frequency of the piezoelectric resonant circuit.

15. The method as claimed in claim 1, wherein the applied layer comprises one of a resistive layer and a capacitor electrode, and wherein determining the removal profile comprises setting an impedance of one of a resistor including the resistive layer and a capacitor including the capacitor electrode.

16. The method as claimed in claim 1, wherein the applied layer comprises a plurality of portions respectively associated with a plurality of diaphragms, and wherein guiding the ion beam comprises removing a first portion of the applied layer to produce a first diaphragm having a first mechanical parameter, and removing a second portion of the applied layer to produce a second diaphragm having a second mechanical parameter, wherein the first mechanical parameter is different from the second mechanical parameter.

17. A method for producing a first piezoelectric resonant circuit having a first natural frequency and a second piezoelectric resonant circuit having a second natural frequency, the first and second piezoelectric resonant circuits being formed on a substrate, the method comprising:
depositing a layer on the substrate such that a first portion of the layer forms a first electrode of the first piezoelectric resonant circuit, and a second portion of the layer forms a second electrode of the second piezoelectric resonant circuit, and such that the first piezoelectric resonant circuit has a third natural frequency, and such that the second piezoelectric resonant circuit has a fourth natural frequency;
etching, using an ion beam, a first amount of material from the first electrode until the third natural frequency of the first piezoelectric resonant circuit changes to the first natural frequency; and
etching, using the ion beam, a second amount of material from the second electrode until the fourth natural frequency of the second piezoelectric resonant circuit changes the second natural frequency.

18. The method according to claim 17,
wherein depositing the layer comprises forming the first portion of the layer with a first thickness, and forming the second portion of the layer with a second thickness, wherein the first thickness equals the second thickness,
wherein etching the first electrode comprises reducing the first thickness of the first portion of the layer by a first amount, and
wherein etching the second electrode comprises reducing the second thickness of the second portion of the layer by a second amount, the second amount being different from the first amount.

19. The method according to claim 18, wherein etching comprises generating said ion beam such that the ion beam has a diameter in the range of 1 mm and 100 mm.

20. The method according to claim 19, wherein the ion beam has a diameter in the range of 5 mm and 50 mm.
